(19) United States
(12) Patent Application Publication
(10) Pub. No.: US 2025/0210429 A1
(43) Pub. Date: Jun. 26, 2025

(54) INTEGRATED CIRCUIT PACKAGES WITH STIFFENERS CONTAINING SEMICONDUCTOR DIES AND ASSOCIATED METHODS

(71) Applicant: Intel Corporation, Santa Clara, CA (US)

(72) Inventors: Jackson Chung Peng Kong, Tanjung Tokong (MY); Bok Eng Cheah, Gelugor (MY); Chin Lee Kuan, Bayan Lepas (MY); Seok Ling Lim, Bukit Mertajam (MY); Jenny Shio Yin Ong, Bayan Lepas (MY)

(73) Assignee: Intel Corporation, Santa Clara, CA (US)

(21) Appl. No.: 19/075,114

(22) Filed: Mar. 10, 2025

(51) Int. Cl. H01L 23/24; H01L 21/48; H01L 21/56; H01L 23/00; H01L 23/31; H01L 23/373; H01L 23/473; H01L 23/538; H01L 25/18; H10B 80/00; H10D 80/30

(52) U.S. Cl. CPC H01L 23/24; H01L 23/3135; H01L 23/3737; H01L 23/473; H01L 23/5385; H01L 23/5386; H01L 25/18; H01L 21/4853; H01L 21/4871; H01L 21/56; H01L 24/16; H01L 24/32; H01L 24/73; H01L 2224/16145; H01L 2224/16225; H01L 2224/32145; H01L 2224/32265; H01L 2224/73204; H01L 2924/1432; H10B 80/00; H10D 80/30

(57) ABSTRACT

Integrated circuit packages with stiffeners containing semiconductor dies and associated methods are disclosed. An example apparatus includes: a base die coupled to a package substrate; a stiffener adjacent the base die, the stiffener including a cavity; and a semiconductor die different from the base die. The semiconductor die is in the cavity in the stiffener. The example apparatus also includes a bridge to electrically couple the semiconductor die to the base die.

### BACKGROUND

As technology advances, there are increasing demands for integrated circuit packages with more processing capability and/or more memory capacity. Efforts to satisfy such demands are often focused on reducing the size and/or density of transistors and/or increasing the size of the overall package.

### BRIEF DESCRIPTION OF THE DRAWINGS

FIG. 1 is a cross-sectional side view of an example integrated circuit package constructed in accordance with teachings disclosed herein.

FIG. 2 is a top view of the example integrated circuit package of FIG. 1.

FIG. 3 is a cross-sectional side view of another example integrated circuit package constructed in accordance with teachings disclosed herein.

FIG. 4 is a top view of the example integrated circuit package of FIG. 3.

FIGS. 5-12 illustrates different stages in an example process to fabricate the example integrated circuit package of FIGS. 1 and 2.

FIG. 13 is a flowchart of an example process to fabricate any of the example integrated circuit packages disclosed herein.

FIG. 14 is a top view of a wafer including dies that may be included in an IC package constructed in accordance with teachings disclosed herein.

FIG. 15 is a cross-sectional side view of an IC device that may be included in an IC package constructed in accordance with teachings disclosed herein.

FIG. 16 is a cross-sectional side view of an IC device assembly that may include an IC package constructed in accordance with teachings disclosed herein.

FIG. 17 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

As technology has advanced, there is an increased demand for high performance computing (e.g., artificial intelligence (AI) applications) associated with higher memory capacity and/or higher processing capabilities. To meet the demands for higher performance, some modern integrated circuit (IC) packages include larger and/or an increased number of semiconductor dies (e.g., also known as chips, chiplets, or tiles) for memory (referred to herein as memory dies) and/or for processing (referred to herein as processor dies). Example types of memory dies include dynamic random-access memory (DRAM) dies, high-bandwidth memory (HBM) dies, etc. Example types of processor dies include central processing units (CPUs), graphics processing units (GPUs), neural network processing units (NPUs), tensor processing unit (TPU), etc.

Increases in the size and/or amount of memory dies and/or processor dies within a package can result in an increased size of the package contrary to competing demands for device miniaturization. More particularly, increases in package size can correspond to a larger X-Y footprint of the package if the dies are individually enlarged and/or more dies are placed side-by-side. Additionally or alternatively, increases in package size can correspond to a greater Z-height (e.g., thickness) of the package when the dies are stacked on top of one another. Moreover, as more and/or larger dies are included in a package, the underlying base die and/or interposer that facilitates communication between the different dies in the package may also need to increase in size.

Existing solutions to mitigate against increased Z-heights for stacked memory dies include die thinning (e.g., reducing the thickness of each memory die to below 25 micrometers (μm)). Existing solutions to mitigate against increased X-Y footprint of dies includes form-factor miniaturization (e.g., using through-silicon vias (TSVs) and/or reducing bump pitch to enable higher density devices without a corresponding increase in form-factor expansion). While these known approaches are helpful, they have not kept pace with increasing demands for higher capacity devices, leading to increasing form-factors.

In addition to going counter to demands for miniaturization, larger semiconductor dies and associated larger packages (needed to meet demands for high performance computing) also increase the risk of warpage that can negatively impact manufacturing yield and/or the reliability of the packages. One approach to mitigate against warpage is the use of a stiffener in a package. More particularly, in some instances, a rigid metal plate can be affixed to a package substrate of an IC package adjacent to the semiconductor dies also mounted on to the package substrate. While stiffeners help reduce warpage, the stiffeners necessarily take up space, thereby leading to further enlargement to the form-factor of IC packages.

Example IC packages disclosed herein include one or more semiconductor dies within a cavity or recess in a stiffener. That is, additional memory and/or processing capacity and/or capability can be added to a package without increasing its size by providing cavities in the stiffener and then positioning one or more semiconductor dies within respective ones of the cavities. Alternatively, the same amount of memory and/or processing capacity/capabilities can be achieved in a smaller package than is currently possible by respectively relocating some of the memory and/or processing capacity/capability into smaller semiconductor dies placed in cavities within a stiffener and implementing a remainder of the memory and/or processing capacity/capability with other smaller semiconductor dies outside of the cavities of the stiffener. By reducing the size of semiconductor dies in this manner, product assembly yield and/or throughput can be improved. Furthermore, smaller dies generally cause less warpage, thereby enabling improved warpage control. Further still, in some examples, the cavities in the stiffener do not extend all the way through the stiffener so that the stiffener can still provide the structural support to reduce (e.g., avoid) warpage. Examples disclosed herein have the additional advantage of improved thermal dissipation as a result of the dies being smaller and more dispersed or distributed throughout the package (including within the stiffener).

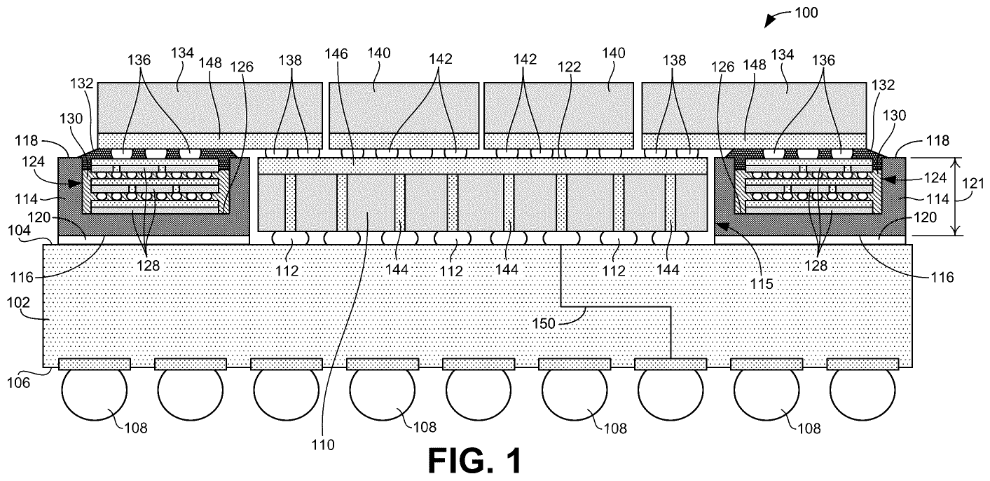

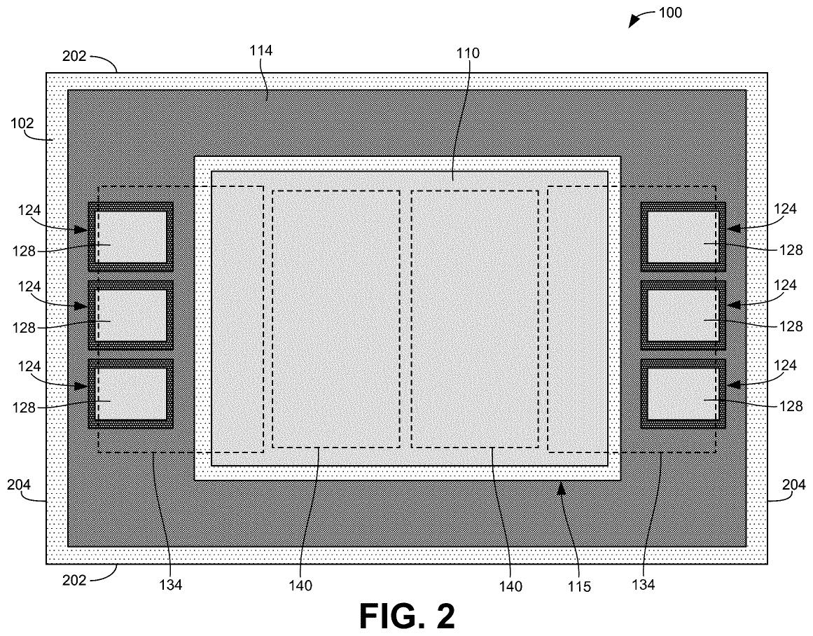

FIG. 1 illustrates an example integrated circuit (IC) package 100 constructed in accordance with teachings disclosed herein. FIG. 2 is a top view of the example IC package 100 of FIG. 1. In the illustrated example, the IC package 100 includes a package substrate 102 having a first side 104 (e.g., a first surface, a die mounting surface, a top surface) and a second side 106 (e.g., a second surface, a package mounting surface, a bottom surface, an external surface) opposite the first side 104. As shown in the illustrated examples, the second side 106 of the package substrate 102 includes an array of first contacts 108 that enable the IC package 100 to be electrically coupled to an underlying substrate (e.g., a printed circuit board (PCB)). In the illustrated example, the first contacts 108 are represented as balls (e.g., solder balls) in a ball grid array (BGA). However, in some examples, the IC package 100 may include bumps, pads, lands, pins, solder joints, combinations of metallic (e.g., copper) pillars and solder, and/or any other type(s) of contacts in addition to or instead of the balls shown to enable the electrical coupling of the IC package 100 to an underlying substrate.

In this example, a base die 110 (e.g., a first semiconductor die) is mounted directly to the package substrate 102 via an array of second contacts 112. In the illustrated example, the second contacts 112 are represented as micro-balls. However, in some examples, the base die 110 is coupled to the package substrate 102 via bumps, pads, lands, pins, solder joints, combinations of metallic (e.g., copper) pillars and solder, and/or any other type(s) of contacts in addition to or instead of the micro-balls shown in FIG. 1. In some examples, the base die 110 includes a silicon substrate. In other examples, the base die 110 includes a glass substrate. In other examples, the base die 110 includes a ceramic substrate.

In the example shown in FIGS. 1 and 2, the IC package 100 includes a stiffener 114 that at least partially surrounds the base die 110. In some examples, the stiffener 114 includes a metal (e.g., aluminum, stainless steel, etc.) that is more rigid than the package substrate 102. In some examples, as shown in FIG. 2, the stiffener 114 completely surrounds the base die 110. That is, the base die 110 is positioned within a central opening 115 (e.g., a through-hole) in the stiffener 114. In other examples, the stiffener 114 is adjacent to and partially surrounds the base die 110 without completely encircling the base die 110. The stiffener 114 includes a first surface 116 that faces towards the package substrate 102 and a second surface 118 that faces away from the package substrate 102 (e.g., opposite to the first surface 116). In some examples, the stiffener 114 is attached (e.g., affixed, mounted) to the first side 104 of the package substrate 102 via an adhesive 120. In some examples, the stiffener 114 is dimensioned (e.g., with a thickness 121) so that the second surface 118 is substantially flush with a top surface 122 of the base die 110. As used herein, substantially flush means within 60 μm or less (e.g., within 50 μm, within 30 μm, within 20 μm, etc.) of exactly flush. In some examples, the thickness is between approximately 100 μm and approximately 500 μm. However, in other examples, the thickness 121 can be less than 100 μm or more than 500 μm.

In some examples, the stiffener 114 includes one or more cavities 124 (e.g., recesses, openings, trenches, holes) that extend from a second surface 118 of the stiffener 114 towards the first surface 116. However, in this example, the cavities 124 extend less than the full thickness 121 of the stiffener 114. Thus, the cavities 124 are defined by recessed surfaces 126 (e.g., inset surfaces) of the stiffener 114 that are recessed or inset relative to the second surface 118 of the stiffener 114. In some examples, the cavities 124 extend any suitable proportion of the thickness 121 of the stiffener 114 (e.g., at least 10%, at least 15%, at least 25%, at least 30%, at least 50%, at least 75%, at least 80%, at least 85%, etc.). In some examples, the recessed surfaces 126 of different ones of the cavities 124 are at different depths relative to one another. In some examples, one or more of the cavities 124 extend all the way through the thickness 121 of the stiffener 114.

In the illustrated example of FIG. 1, different ones of the cavities 124 include different semiconductor dies. More particularly, in this example, the cavities 124 include a stack of memory dies 128 (e.g., second semiconductor (e.g., silicon) dies, HBM dies, DRAM dies). In this example, the different memory dies 128 in each stack are operatively coupled via corresponding arrays of micro-bumps at the interface between adjacent pairs of the memory dies 128. However, the memory dies 128 can be coupled in any other suitable manner. Further, in some examples, non-adjacent ones of the memory dies 128 are electrically (e.g., conductively) coupled by TSVs extending through intermediate ones of the dies 128 in the stack. Although the memory stacks are shown as including three memory dies 128, in other examples, the stacks can include a different number of memory dies 128 greater or less than three (e.g., 2, 4, 5, 6, etc.). In some examples, only one memory die 128 is included in the stack. In some examples, different ones of the cavities 124 include stacks with different numbers of memory dies 128.

In this example, gaps between the stack of memory dies 128 and walls of the cavities 124 are filled with a thermally conductive material 130 that is in contact with the memory dies 128 to facilitate heat transfer from the memory dies 128 to the stiffener 114. In some examples, the stack of memory dies 128 is shorter than the depth of the recessed surface 126. As such, in some examples, the stack of memory dies 128 is spaced apart from the recessed surface 126 to define a gap therebetween that is also filled by the thermally conductive material 130. However, in other examples, such as is shown in the illustrated example, the stack of memory dies 128 extends up to and/or is affixed to (e.g., via an adhesive) the recessed surfaces 126.

In some examples, the thermally conductive material 130 includes a thermal paste. In some examples, the thermally conductive material 130 includes a thermally conductive polymer. In some examples, the thermally conductive material 130 includes a liquid coolant contained within the cavities 124. That is, in some examples, the memory dies 128 are submerged in a liquid that is able to draw out heat generated by the memory dies 128. In some examples, the liquid coolant is an ethylene glycol-based coolant. In some examples, a sealant 132 closes off (e.g., seals, covers) the cavities 124 to prevent leakage of the thermally conductive material 130. In some examples, the sealant 132 covers at least some of the second surface 118 of the stiffener 114. In some examples, the sealant 132 extends at least partially into the cavities 124. In some examples, the sealant 132 includes an epoxy. In some examples, when the thermally conductive material 130 is a solid and, thus, poses no risk of leakage, the sealant 132 is omitted.

In the illustrated example of FIGS. 1 and 2, the IC package 100 includes bridge dies 134 (e.g., third semiconductor (e.g., silicon) dies) that communicatively couple the stack of memory dies 128 with the base die 110. In the illustrated example of FIG. 2, the bridge dies 134 are demarcated with dashed lines and represented as see-through to provide a view of the underlying components. In some examples, the bridge dies 134 include a silicon substrate. In other examples, the bridge dies 134 include a glass substrate. In other examples, the bridge dies 134 include a ceramic substrate.

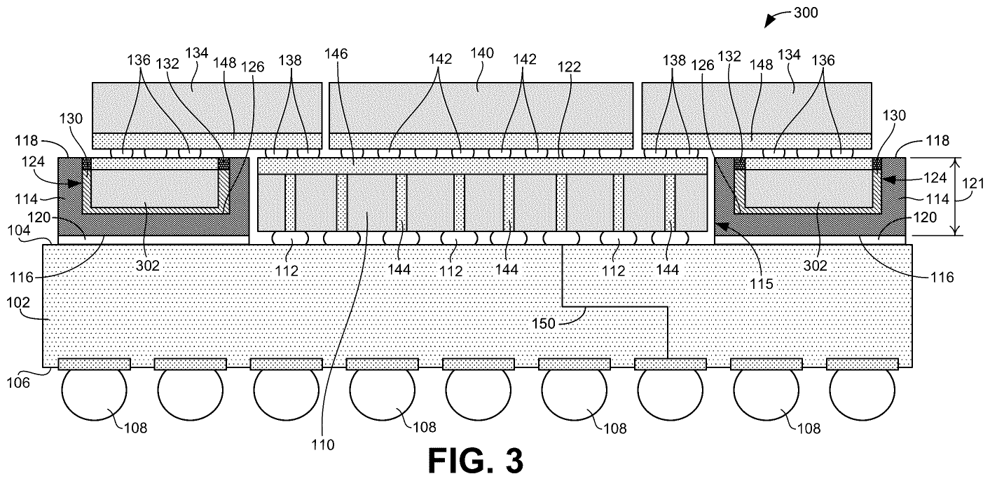

As shown in the illustrated example, the bridge dies 134 are coupled to the stack of memory dies 128 via third contacts 136 and coupled to the base die 110 via fourth contacts 138 by extending across (e.g., over) at least a portion of the stiffener 114 between the memory dies 128 and the base die 110. In this example, the portion of the stiffener 114 defines a sidewall of the cavities 124. In the illustrated example of FIG. 1, the third and fourth contacts 136, 138 are represented as micro-bumps. However, in some examples, the bridge dies 134 connect to the memory dies 128 and/or the base die 110 via balls, pads, lands, pins, solder joints, combinations of metallic (e.g., copper) pillars and solder, and/or any other type(s) of contacts in addition to or instead of the micro-bumps shown in FIG. 1. In this example, the sealant 132 also serves as an underfill material that encapsulates (e.g., encases, surrounds) the third contacts 136 between the memory dies 128 and the bridge dies 134. In some examples, the sealant 132 also encapsulates the fourth contacts 138 between the bridge dies 134 and the base die 110. In some examples, the sealant 132 is spaced apart from both the third and fourth contacts 136, 138 (as shown below in connection with FIG. 3). In some such examples, a separate underfill material is employed. In some such examples, the second surface 118 of the stiffener 114 is substantially flush with the top surface 122 of the base die 110 to facilitate the attachment of the third and fourth contacts 136, 138 which are the same size. However, in some examples, the third contacts 136 are a different size relative to the fourth contacts 138 (e.g., the fourth contacts 138 connecting to the bridge die(s) 134 to the base die 110 may be smaller (e.g., below 25 um) and the third contacts 136 connecting the bridge die(s) 134 to the memory dies 128 in the cavities 124 of the stiffener 114 may be larger (ranging from approximately 25 μm to 100 um). In some such examples, larger height tolerance between the second surface 118 of the stiffener and the top surface 122 of the base die 110 can be tolerated. That is, in some examples, the second surface 118 of the stiffener and the top surface 122 are not substantially flush.

In the illustrated example of FIGS. 1 and 2, the IC package 100 includes two processor dies 140 (e.g., fourth semiconductor (e.g., silicon) dies) that are communicatively couple to the base die 110 via fifth contacts 142. In the illustrated example of FIG. 1, the fifth contacts 142 are represented as micro-bumps. However, in some examples, the processor dies 140 connect to the base die 110 via balls, pads, lands, pins, solder joints, combinations of metallic (e.g., copper) pillars and solder, and/or any other type(s) of contacts in addition to or instead of the micro-bumps shown in FIG. 1. In some examples, the sealant 132 can extend over the base die 110 to encapsulate and/or fill gaps between the fifth contacts 142 associated with the processor dies 140. In some examples, a different underfill material is positioned between the base die 110 and the processor dies 140 to encapsulate and/or surround the fifth contacts 142.

In the illustrated example of FIG. 2, the processor dies 140 are demarcated with dashed lines and represented as see-through to provide a view of the underlying components. The processor dies 140 can be any suitable type of processor die (e.g., a CPU die, a GPU die, an NPU die, a TPU die, etc.). In some examples, the two processor dies 140 are the same type of die (e.g., two CPU dies). In other examples, the two processor dies 140 can be different types (e.g., one CPU die and one GPU die). While the example IC package 100 of FIGS. 1 and 2 includes two processor dies 140, in other examples, the IC package 100 may have only one processor die or more than two processor dies.

In some examples, all of the semiconductor dies 110, 128, 134, 140 and the stiffener 114 are enclosed by a package lid (e.g., a mold compound, an integrated heat spreader (IHS)). However, in other examples (as shown), the package lid is omitted. In some examples, the IC package 100 includes additional passive components, such as surface-mount resistors, capacitors, and/or inductors disposed on the package mounting surface 106 of the package substrate 102 and/or the die mounting surface 104 of the package substrate 102.

In some examples, the base die 110 and/or the bridge dies 134 include active components (e.g., transistors) to perform any suitable functions (e.g., processing functions, memory functions, etc.). In some such examples, the bridge dies 134 can provide similar functionality to the processor dies 140 and/or the memory dies 128. In some examples, the processor dies 140 can be omitted with the bridge dies 134 providing their functionality. That is, in some examples, the bridge dies 134 are expanded across the base die 110 and implemented with circuitry corresponding to the processor dies 140. Thus, in some examples, the bridge dies 134 can also be referred to as processor dies. In other examples, the base die 110 and the bridge dies 134 are implemented as interposers (e.g., interposer dies, silicon interposers) or other passive components with no active components (e.g., no transistors). That is, in some examples, the base die 110 and the bridge dies 134 are limited to providing electrical routing or traces (e.g., within respective metal redistribution layers (RDLs) 146, 148) to electrically couple the different components of the IC package 100. For instance, in some examples, the bridge dies 134 provide electrical paths (e.g., for communication signals and/or power delivery) between the stacks of memory dies 128 and the base die 110. Further, the base die 110 provides electrical paths (e.g., for communication signals and/or power delivery) from the bridge dies 134 to the processor dies 140 and/or between the processor dies 140. Further, in some examples, the base die 110 provides electrical paths (e.g., for communication signals and/or power delivery) between the processor dies 140 and/or the memory dies 128 (via the bridge dies 134) to the package substrate 102 by way of through-silicon vias (TSVs) 144 extending through the base die 110 from the redistribution layer 146 to the second contacts 112. In FIG. 1, the redistribution layers 146, 148 are shown as a single layer for purposes of clarity and simplicity but can include multiple layers of metal traces or routing separated by layers of intermetal dielectric material and interconnected by metal vias. The package substrate 102 includes internal interconnects 150 (only one of which is shown) that electrically couple the second contacts 112 with the first contacts 108, thereby enabling any of the dies 110, 128, 134, 140 to communicate with components external to IC package 100 (e.g., via a printed circuit board (PCB) to which the first contacts 108 are communicatively coupled).

As shown in the illustrated example of FIG. 2, the IC package 100 is rectangular with longer sides 202 and shorter sides 204. In this example, the cavities 124 (and associated memory dies 128) are arranged within the stiffener 114 along the shorter sides 204. However, in other examples, the cavities 124 can additionally or alternatively be arranged along the longer sides 202 of the package 100. Further, while the arrangement of the cavities 124 are symmetrical with three cavities 124 on each side 204, in other examples, the cavities 124 can be in non-symmetrically arranged with different numbers of cavities 124 on either side and/or the cavities in non-symmetrical positions. In other words, the stiffener 114 can include any suitable number of cavities 124 at any suitable location(s). Further, the cavities 124 can be larger or smaller than what is shown in the illustrated example of FIG. 2. Moreover, in some examples, different ones of the cavities 124 can be different sizes (e.g., to house different sizes of dies 128). Further, in some examples, different ones of the cavities 124 can include different types of semiconductor dies. For instance, in some examples, at least some of the memory dies 128 within one or more cavities 124 is replaced with one or more processor dies. Similarly, in some examples, one or more memory die can be positioned on top of the base die 110 (e.g., adjacent to and/or instead of one of the processor dies 140).

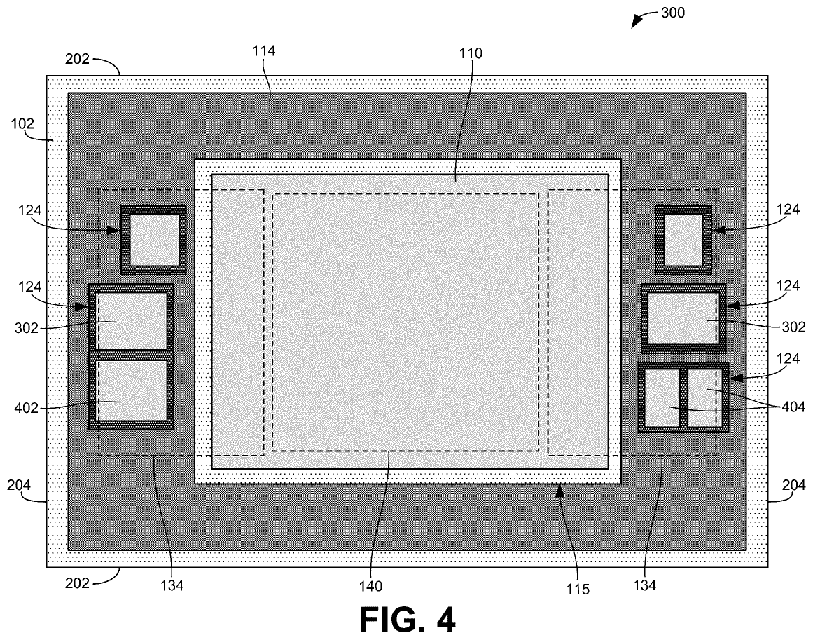

FIG. 3 illustrates another example integrated circuit (IC) package 300 constructed in accordance with teachings disclosed. FIG. 4 is a top view of the example IC package 300 of FIG. 3. The example IC package 300 of FIGS. 3 and 4 is similar to the example IC package 100 of FIGS. 1 and 2 except as noted below or otherwise made clear from the context. Thus, the same or similar features are identified by the same reference numbers and the description of such features provided above applies equally to the corresponding features shown in FIGS. 3 and 4.

The example shown in FIG. 3 differs from the example shown in FIG. 1 in that the example of FIG. 3 includes additional processor dies 302 (e.g., fifth semiconductor (e.g., silicon) dies) that individual fill a substantial majority of corresponding ones of the cavities 124 (rather than including a stack of multiple memory dies 128). As shown in the illustrated example of FIG. 3, the additional processor dies 302 are spaced apart from the recessed surface 126 to define a gap therebetween that is filled by the thermally conductive material 130. However, in other examples, the additional processor dies 302 can extend up to and/or be affixed to (e.g., via an adhesive) the recessed surfaces 126.

In some examples, the additional processor dies 302 are NPUs. Further, in some such examples, the bridge dies 134 coupled to each NPU (e.g., each of the additional processor dies 302 within the cavities 124) is a System-on-a-Chip (SoC) that is in communication with and relies on the computational capacity of the associated additional processor die 302. Providing disaggregated NPU tiles within cavities 124 of a stiffener 114 that are peripheral to other dies (e.g., the SoC implemented in the bridge dies 134 and/or processor die 140) can help achieve scalable compute performance for high performance applications such as artificial intelligence and/or machine learning. More particularly, the proximity of the NPU dies (e.g., the additional dies 302) to the main computing units (e.g., the SoC implemented in the bridge dies 134) allows for better device responses than known platforms with discrete NPU solutions. Additionally, the example assembly shown in FIGS. 3 and 4 can provide power delivery network (PDN) loadline mitigation (e.g., as compared with integrated circuits where the NPU is integrated in an SoC in which space for power planes is much more constrained leading to power delivery impedance). In other words, placing disaggregated NPU tiles within the stiffener 114 provide system power and battery life benefits by reallocating the power plane associated with the NPU tiles. Further, such examples provide a low NPU loadline that is critical for AI performance boost. More particularly, NPU count is an important factor for AI workload scaling. Disaggregated NPU tiles (e.g., within the stiffener 114) offers the scaling of the NPU count without significantly growing the footprint of the SoC, the base die 110, and the resulting overall package 100.

Another difference between the examples shown in FIGS. 1 and 3 is that the sealant 132 (that helps retain the thermally conductive material 130 within the cavities 124) is spaced apart from the third contacts 136 connecting the additional processor dies 302 to the bridge dies 134. More particularly, in some examples, the sealant 132 is retained within the cavities 124 with an outer surface of the sealant 132 substantially flush with the second surface 118 of the stiffener 114. In some examples, the outer surface of the sealant 132 is recessed relative to the second surface 118.

In contrast with FIGS. 1 and 2, in the illustrated example of FIGS. 3 and 4, the IC package 300 includes only a single processor die 140. However, as discussed above in connection with FIGS. 1 and 2, the IC package 300 of FIGS. 3 and 4 can include any suitable number of processor dies 140.

Additional differences between the IC package 100 of FIGS. 1 and 2 and the IC package 300 of FIGS. 3 and 4 are made apparent with reference to FIGS. 2 and 4. Specifically, as shown in the illustrated example of FIG. 4, different ones of the cavities 124 are different sizes and positioned in a non-symmetrical arrangement. In some examples, different ones of the cavities 124 are arranged in a linear configuration, as in the case of the cavities 124 on the right side of the example shown in FIG. 4. In some examples, different ones of the cavities 124 are laterally offset and arranged in a non-linear configuration, as in the case of the cavities 124 on the left side of the example shown in FIG. 4. Further, as shown in the illustrated example, some of the cavities 124 include multiple dies that are positioned side-by-side. Specifically, on the left side of FIG. 4, one of the cavities 124 includes a first one of the additional processor dies 302 and one other die 402 arranged side-by-side in a direction parallel with the shorter side 204 of the IC package 300. On the right side of FIG. 4, one of the cavities 124 includes two more dies 404 arranged side-by-side in a direction perpendicular to the shorter side 204 of the IC package 300. In other examples, multiple dies can be arranged in any other suitable manner within a given cavity 124. In some examples, the different dies in a given cavity are the same type of die. In other examples, the different dies in a given cavity can be different types. In some examples, the arrangement of the dies within the cavities 124 are designed to allow direct (e.g., shortest possible) connections between the bridge dies 134 and the dies/tiles within the cavities 124 according to a given (e.g., optimized) circuitry block location or floorplan of the bridge dies 134.

The foregoing examples of IC packages 100, 300 of FIGS. 1-4 teach or suggest different features. Although each example IC package 100, 300 disclosed above has certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features.

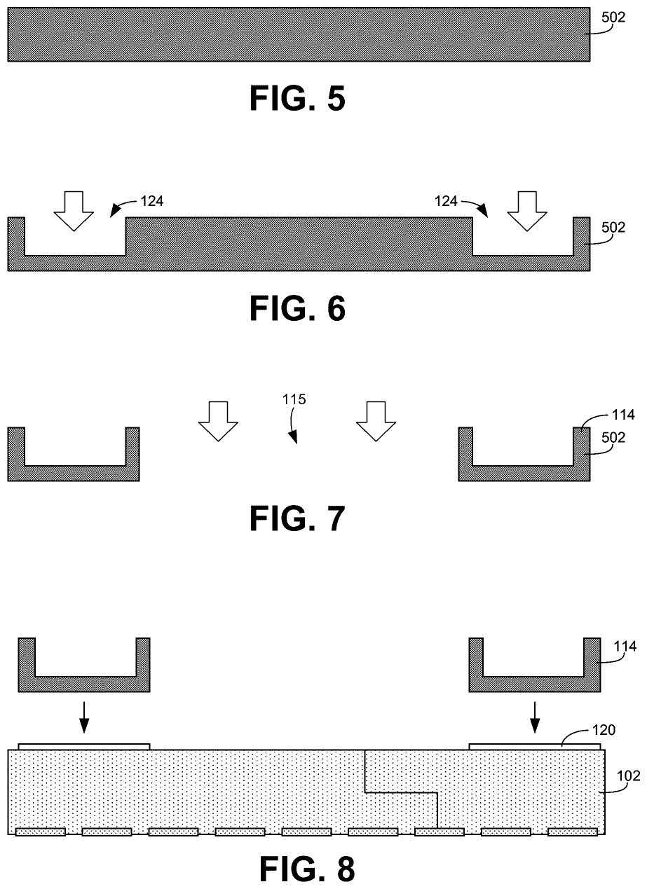

FIGS. 5-12 illustrates different stages in an example process to fabricate the example integrated circuit package 100 of FIGS. 1 and 2. Although the FIGS. 5-12 are described with respect to FIGS. 1 and 2, similar stages of fabrication can be followed to produce the example IC package 300 of FIGS. 3 and 4 and/or any other IC package constructed in accordance with teachings disclosed herein.

FIG. 5 illustrates an example sheet of metal as a starting point to fabricate the example stiffener 114 to be used in the IC package 100 of FIG. 1. In some examples, the sheet of metal 502 is fabricated with a thickness corresponding to the thickness 121 of the stiffener 114. FIG. 6 represents the stage of fabrication in which the cavities 124 for the stiffener 114 are provided within the sheet of metal 502. The cavities 124 can be formed using any suitable process (e.g., mechanical drilling, milling, and/or grinding). FIG. 7 represents the stage of fabrication in which the central opening 115 is provided in the sheet of metal 502 to define the final shape of the stiffener 114. The central opening 115 can be formed using any suitable process (e.g., mechanical drilling, milling, and/or grinding). In some examples, the central opening 115 is provided before and/or at the same time that the cavities 124 are provided in the sheet metal 502.

FIG. 8 represents the stage of fabrication in which the stiffener 114 is attached (e.g., mounted, affixed) to the package substrate 102. In this example, the package substrate 102 is fabricated in parallel to the stiffener 114 using any suitable fabrication processes. In some examples, the stiffener 114 is attached by first applying the adhesive 120 to the die mounting surface 104 of the package substrate 102 and then attaching the stiffener 114 (e.g., via a hot press and/or lamination process).

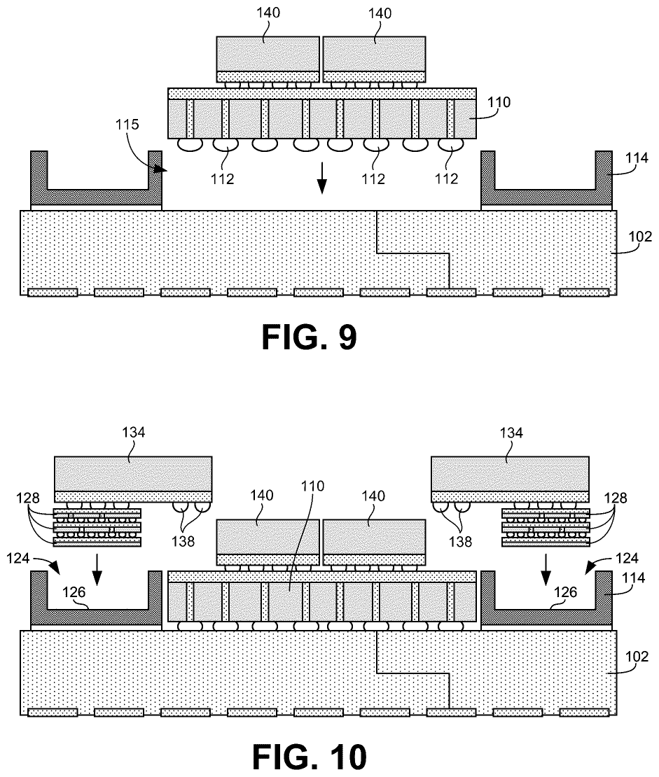

FIG. 9 represents the stage of fabrication in which the base die 110 and the processor dies 140 are attached to the package substrate 102 (e.g., through the central opening 115 in the stiffener 114). In some examples, this stage in the process is achieved by attaching the second contacts 112 on the base die 110 to the package substrate 102 via a solder reflow process (e.g., thermal compression bonding). In this example, the base die 110 and the processor dies 140 are fabricated in parallel to the stiffener 114 and the package substrate 102 using any suitable fabrication processes. Further, in this example, the processor dies 140 are attached or mounted to the base die 110 prior to the combined assembly being attached to the package substrate 102. However, in some examples, the base die 110 is attached to the package substrate 102 before the processor dies 140 are attached to the base die 110. Further, in some examples, the stiffener 114 is attached to the package substrate 102 after the base die 110 is attached (and can be done so before or after the processor dies 140 are attached to the base die 110).

FIG. 10 represents the stage of fabrication in which the memory dies 128 and the bridge dies 134 are attached to the rest of the components in the IC package 100. In some examples, this stage in the process is achieved by attaching the fourth contacts 138 on the bridge dies 134 to the base die 110 via a solder reflow process (e.g., thermal compression bonding). In this example, the memory dies 128 and the bridge dies 134 are fabricated in parallel to the other components in the IC package 100 using any suitable fabrication processes. Further, in this example, the memory dies 128 are attached or mounted to the bridge dies 134 prior to the combined assembly being inserted into the cavities 124 and attached to the base die 110. In this way, it is possible to position the memory dies 128 spaced apart from the recessed surface 126 (similar to what is shown in connection with the additional processor dies 302 of FIG. 3). However, in other examples, the stacks of memory dies 128 are placed within the cavities 124 of the stiffener 114 before the bridge dies 134 are attached. That is, in some examples, the bridge dies 134 are attached to both the memory dies 128 and the base dies 110 simultaneously. In such examples, the stacks of memory dies 128 rest upon the recessed surface 126. In some such examples, the memory dies 128 are positioned in the cavities 124 of the stiffener 114 prior to the stiffener 114 being attached to the package substrate 102. In some examples, the stacks of memory dies 128 are affixed to the recessed surface 126 of the cavities 124 (e.g., via an adhesive) to help hold the memory dies 128 in place.

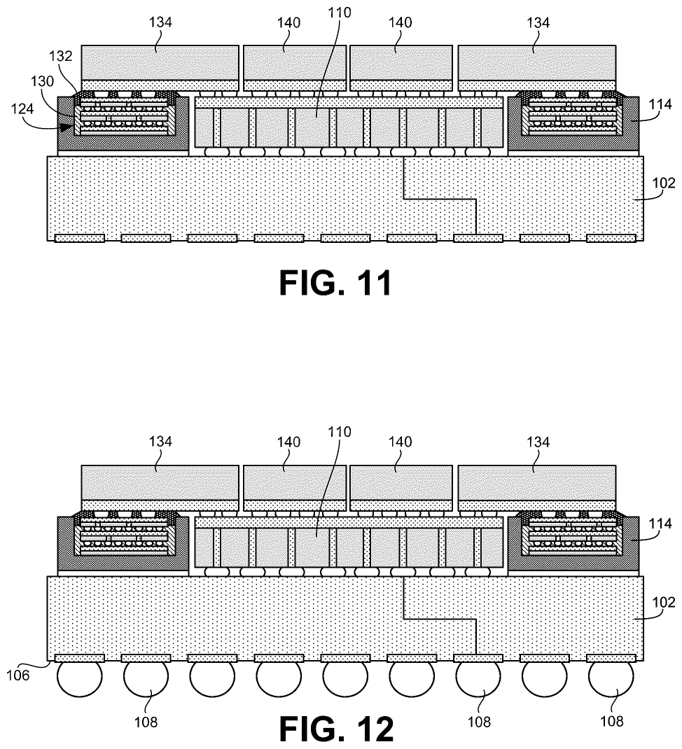

FIG. 11 represents the stage of fabrication after which the thermally conductive material 130 is deposited within the cavities 124 to fill in the gaps between the memory dies 128 and the walls of the cavities 124. Further, FIG. 11 represents the stage of fabrication following the placement of the sealant 132 to enclose the thermally conductive material 130 within the cavities 124. The thermally conductive material 130 and/or the sealant 132 can be deposited using any suitable process (e.g., dispensing process, injection process, etc.). In some examples, the depositing of the thermally conductive material 130 and/or the sealant 132 is followed by a curing process so the material can set and/or harden. In some examples, the thermally conductive material 130 is deposited into the cavities 124 prior to the memory dies 128 being inserted therein.

FIG. 12 represents the stage of fabrication following the attachment of solder balls (e.g., the first contacts 108) onto the package mounting surface 106 of the package substrate 102. The first contacts 108 can be added using any suitable attachment process (e.g., a surface mounting process, a solder reflow process, etc.). FIG. 12 represents the completion of the fabrication and assembly of the IC package 100 shown in FIG. 1.

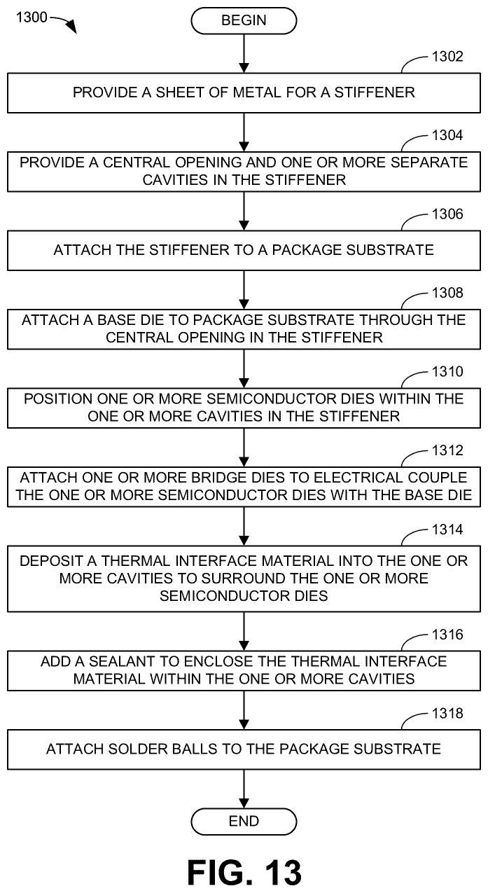

FIG. 13 is a flowchart representative of an example method 1300 of manufacturing the example IC package 100 of FIGS. 1 and 2 in line with the stages of manufacture shown in FIGS. 5-12. Although the flowchart of FIG. 13 is described with respect to FIGS. 1 and 2, the example method 1300 can be suitable adapted to manufacture the example IC package 300 of FIGS. 3 and 4 and/or any other IC package constructed in accordance with teachings disclosed herein. In some examples, some or all of the operations outlined in the example method 1300 of FIG. 13 are performed automatically by fabrication equipment that is programmed to perform the operations. Although the example method of manufacture is described with reference to the flowchart illustrated in FIG. 13, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method of FIG. 13 begins at block 1302 by providing a sheet of metal for a stiffener (e.g., as represented in FIG. 5). At block 1304, the example method 1300 involves providing a central opening and one or more separate cavities in the stiffener (e.g., as represented in FIGS. 6 and 7). At block 1306, the example method 1300 involves attaching the stiffener to a package substrate (e.g., as represented in FIG. 8). At block 1308, the example method 1300 involves attaching a base die to a package substrate through the central opening in the stiffener (e.g., as represented in FIG. 9). In some examples, additional dies may already have been mounted onto the base die in a stacked arrangement. In other examples, the additional dies can be added later in the process.

At block 1310, the example method 1300 involves positioning one or more semiconductor dies within the one or more cavities in the stiffener. At block 1312, the example method 1300 involves attaching one or more bridge dies to electrically couple the one or more semiconductor dies with the base die. In some examples, blocks 1310 and 1312 are done simultaneously, such as when the one or more semiconductor dies are first attached to the one or more bridge dies (e.g., as represented in FIG. 10). At block 1314, the example method 1300 involves depositing a thermally conductive material into the one or more cavities to surround the one or more semiconductor dies. In some examples, block 1314 is implemented before block 1310. At block 1316, the example method 1300 involves adding a sealant to enclose the thermally conductive material within the one or more cavities. At block 1318, the example method 1300 involves attaching solder balls to the package substrate. Thereafter, the example method 1300 of FIG. 13 ends.

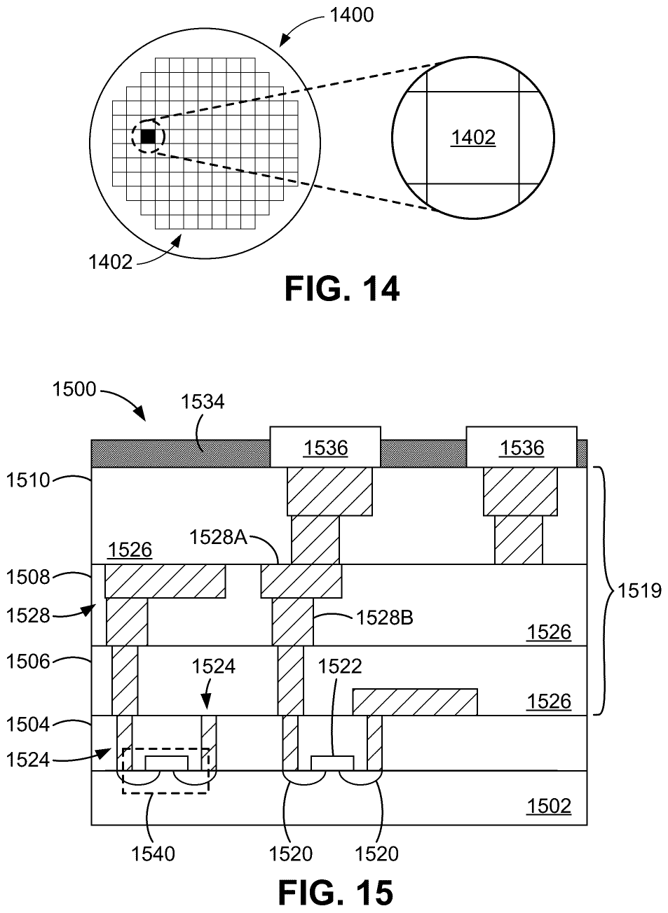

The example IC packages 100, 300 disclosed herein may be included in any suitable electronic component. FIGS. 14-17 illustrate various examples of apparatus that may include or be included in the IC packages 100, 300 disclosed herein.

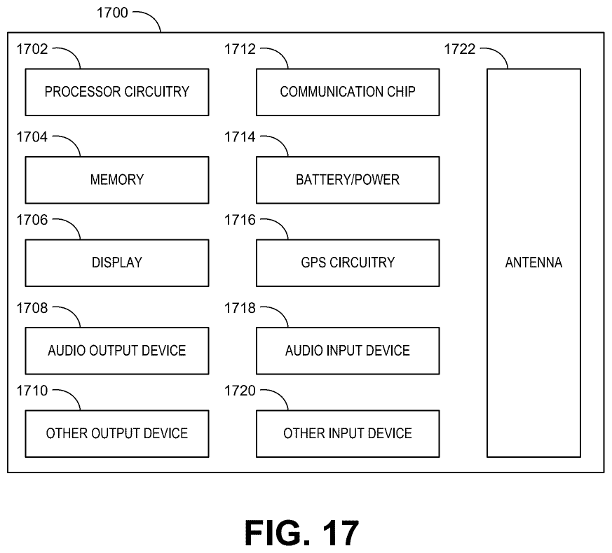

FIG. 14 is a top view of a wafer 1400 and dies 1402 that may be included in the IC package 100, 300 of FIG. 1-4 (e.g., as any suitable ones of the dies 110, 128, 134, 140, 302, 402, 404). The wafer 1400 includes semiconductor material and one or more dies 1402 having circuitry. Each of the dies 1402 may be a repeating unit of a semiconductor product. After the fabrication of the semiconductor product is complete, the wafer 1400 may undergo a singulation process in which the dies 1402 are separated from one another to provide discrete “chips.” The die 1402 includes one or more transistors (e.g., some of the transistors 1540 of FIG. 15, discussed below), supporting circuitry to route electrical signals to the transistors, passive components (e.g., traces, resistors, capacitors, inductors, and/or other circuitry), and/or any other components. In some examples, the die 1402 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 1402. For example, a memory array of multiple memory circuits may be formed on a same die 1402 as programmable circuitry (e.g., the processor circuitry 1702 of FIG. 17) and/or other logic circuitry. Such memory may store information for use by the programmable circuitry. The example IC packages 100, 300 disclosed herein may be manufactured using a die-to-wafer assembly technique in which some dies are attached to a wafer 1400 that includes others of the dies, and the wafer 1400 is subsequently singulated.

FIG. 15 is a cross-sectional side view of an IC device 1500 that may be included in the example IC packages 100, 300 of FIG. 1-4 (e.g., as any suitable ones of the dies 110, 128, 134, 140, 302, 402, 404). One or more of the IC devices 1500 may be included in one or more dies 1402 (FIG. 14). The IC device 1500 may be formed on a die substrate 1502 (e.g., the wafer 1400 of FIG. 14) and may be included in a die (e.g., the die 1402 of FIG. 14). The die substrate 1502 may be a semiconductor substrate including semiconductor materials including, for example, n-type or p-type materials systems (or a combination of both). The die substrate 1502 may include, for example, a crystalline substrate formed using a bulk silicon or a silicon-on-insulator (SOI) substructure. In some examples, the die substrate 1502 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1502. Although a few examples of materials from which the die substrate 1502 may be formed are described here, any material that may serve as a foundation for an IC device 1500 may be used. The die substrate 1502 may be part of a singulated die (e.g., the dies 1402 of FIG. 14) or a wafer (e.g., the wafer 1400 of FIG. 14).

The IC device 1500 may include one or more device layers 1504 disposed on and/or above the die substrate 1502. The device layer 1504 may include features of one or more transistors 1540 (e.g., metal oxide semiconductor field-effect transistors (MOSFETs)) formed on the die substrate 1502. The device layer 1504 may include, for example, one or more source and/or drain (S/D) regions 1520, a gate 1522 to control current flow between the S/D regions 1520, and one or more S/D contacts 1524 to route electrical signals to/from the S/D regions 1520. The transistors 1540 may include additional features not depicted for the sake of clarity, such as device isolation regions, gate contacts, and the like. The transistors 1540 are not limited to the type and configuration depicted in FIG. 15 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1540 may include a gate 1522 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1540 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1540 along the source-channel-drain direction, the gate electrode may include a U-shaped structure that includes a bottom portion substantially parallel to the surface of the die substrate 1502 and two sidewall portions that are substantially perpendicular to the top surface of the die substrate 1502. In other examples, at least one of the metal layers that form the gate electrode may be a planar layer that is substantially parallel to the top surface of the die substrate 1502 and does not include sidewall portions substantially perpendicular to the top surface of the die substrate 1502. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1520 may be formed within the die substrate 1502 adjacent to the gate 1522 of corresponding transistor(s) 1540. The S/D regions 1520 may be formed using an implantation/diffusion process or an etching/deposition process, for example. In the former process, dopants such as boron, aluminum, antimony, phosphorous, or arsenic may be ion-implanted into the die substrate 1502 to form the S/D regions 1520. An annealing process that activates the dopants and causes them to diffuse farther into the die substrate 1502 may follow the ion-implantation process. In the latter process, the die substrate 1502 may first be etched to form recesses at the locations of the S/D regions 1520. An epitaxial deposition process may then be carried out to fill the recesses with material that is used to fabricate the S/D regions 1520. In some implementations, the S/D regions 1520 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1520 may be formed using one or more alternate semiconductor materials such as germanium or a group III-V material or alloy. In further examples, one or more layers of metal and/or metal alloys may be used to form the S/D regions 1520.

Electrical signals, such as power and/or input/output (I/O) signals, may be routed to and/or from the devices (e.g., transistors 1540) of the device layer 1504 through one or more interconnect layers disposed on the device layer 1504 (illustrated in FIG. 15 as interconnect layers 1506-1510). For example, electrically conductive features of the device layer 1504 (e.g., the gate 1522 and the S/D contacts 1524) may be electrically coupled with the interconnect structures 1528 of the interconnect layers 1506-1510. The one or more interconnect layers 1506-1510 may form a metallization stack (also referred to as an “ILD stack”) 1519 of the IC device 1500.

The interconnect structures 1528 may be arranged within the interconnect layers 1506-1510 to route electrical signals according to a wide variety of designs (in particular, the arrangement is not limited to the particular configuration of interconnect structures 1528 depicted in FIG. 15). Although a particular number of interconnect layers 1506-1510 is depicted in FIG. 15, examples of the present disclosure include IC devices having more or fewer interconnect layers than depicted.

In some examples, the interconnect structures 1528 may include lines 1528a and/or vias 1528b filled with an electrically conductive material such as a metal. The lines 1528a may be arranged to route electrical signals in a direction of a plane that is substantially parallel with a surface of the die substrate 1502 upon which the device layer 1504 is formed. For example, the lines 1528a may route electrical signals in a direction in and/or out of the page from the perspective of FIG. 15. The vias 1528b may be arranged to route electrical signals in a direction of a plane that is substantially perpendicular to the surface of the die substrate 1502 upon which the device layer 1504 is formed. In some examples, the vias 1528b may electrically couple lines 1528a of different interconnect layers 1506-1510 together.

The interconnect layers 1506-1510 may include a dielectric material 1526 disposed between the interconnect structures 1528, as shown in FIG. 15. In some examples, the dielectric material 1526 disposed between the interconnect structures 1528 in different ones of the interconnect layers 1506-1510 may have different compositions; in other examples, the composition of the dielectric material 1526 between different interconnect layers 1506-1510 may be the same.

A first interconnect layer 1506 (referred to as Metal 1 or “M1”) may be formed directly on the device layer 1504. In some examples, the first interconnect layer 1506 may include lines 1528a and/or vias 1528b, as shown. The lines 1528a of the first interconnect layer 1506 may be coupled with contacts (e.g., the S/D contacts 1524) of the device layer 1504.

A second interconnect layer 1508 (referred to as Metal 2 or “M2”) may be formed directly on the first interconnect layer 1506. In some examples, the second interconnect layer 1508 may include vias 1528b to couple the lines 1528a of the second interconnect layer 1508 with the lines 1528a of the first interconnect layer 1506. Although the lines 1528a and the vias 1528b are structurally delineated with a line within each interconnect layer (e.g., within the second interconnect layer 1508) for the sake of clarity, the lines 1528a and the vias 1528b may be structurally and/or materially contiguous (e.g., simultaneously filled during a dual-damascene process) in some examples.

A third interconnect layer 1510 (referred to as Metal 3 or “M3”) (and additional interconnect layers, as desired) may be formed in succession on the second interconnect layer 1508 according to similar techniques and/or configurations described in connection with the second interconnect layer 1508 or the first interconnect layer 1506. In some examples, the interconnect layers that are “higher up” in the metallization stack 1519 in the IC device 1500 (i.e., further away from the device layer 1504) may be thicker.

The IC device 1500 may include a solder resist material 1534 (e.g., polyimide or similar material) and one or more conductive contacts 1536 formed on the interconnect layers 1506-1510. In FIG. 15, the conductive contacts 1536 are illustrated as taking the form of bond pads. The conductive contacts 1536 may be electrically coupled with the interconnect structures 1528 and configured to route the electrical signals of the transistor(s) 1540 to other external devices. For example, solder bonds may be formed on the one or more conductive contacts 1536 to mechanically and/or electrically couple a chip including the IC device 1500 with another component (e.g., a circuit board). The IC device 1500 may include additional or alternate structures to route the electrical signals from the interconnect layers 1506-1510; for example, the conductive contacts 1536 may include other analogous features (e.g., posts) that route the electrical signals to external components.

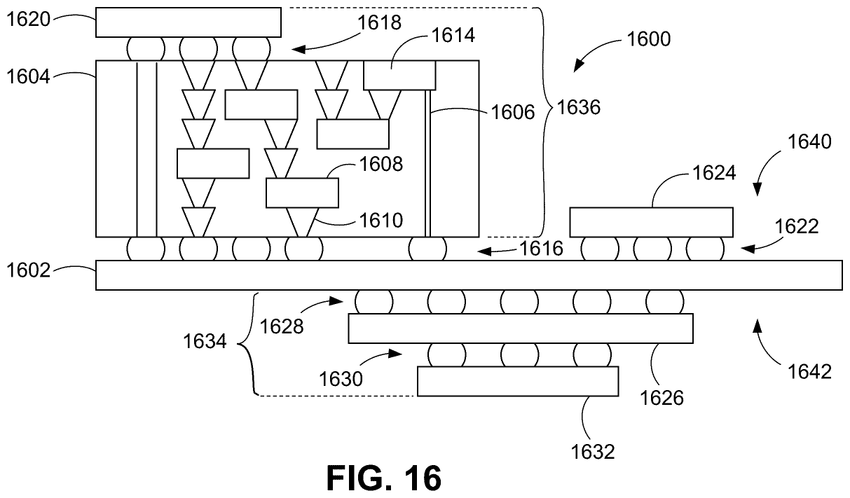

FIG. 16 is a cross-sectional side view of an IC device assembly 1600 that may include one or more of the IC packages 100, 300 disclosed herein. In some examples, the IC device assembly corresponds to one or more of the IC packages 100, 300. The IC device assembly 1600 includes a number of components disposed on a circuit board 1602 (which may be, for example, a motherboard). The IC device assembly 1600 includes components disposed on a first face 1640 of the circuit board 1602 and an opposing second face 1642 of the circuit board 1602; generally, components may be disposed on one or both faces 1640 and 1642. Any of the IC packages discussed below with reference to the IC device assembly 1600 may take the form of the example IC package 100, 300 of FIGS. 1-4.

In some examples, the circuit board 1602 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1602. In other examples, the circuit board 1602 may be a non-PCB substrate.

The IC device assembly 1600 illustrated in FIG. 16 includes a package-on-interposer structure 1636 coupled to the first face 1640 of the circuit board 1602 by coupling components 1616. The coupling components 1616 may electrically and mechanically couple the package-on-interposer structure 1636 to the circuit board 1602, and may include solder balls (as shown in FIG. 16), male and female portions of a socket, an adhesive, an underfill material, and/or any other suitable electrical and/or mechanical coupling structure.

The package-on-interposer structure 1636 may include an IC package 1620 coupled to an interposer 1604 by coupling components 1618. The coupling components 1618 may take any suitable form for the application, such as the forms discussed above with reference to the coupling components 1616. Although a single IC package 1620 is shown in FIG. 16, multiple IC packages may be coupled to the interposer 1604; indeed, additional interposers may be coupled to the interposer 1604. The interposer 1604 may provide an intervening substrate used to bridge the circuit board 1602 and the IC package 1620. The IC package 1620 may be or include, for example, a die (the die 1402 of FIG. 14), an IC device (e.g., the IC device 1500 of FIG. 15), or any other suitable component. Generally, the interposer 1604 may spread a connection to a wider pitch or reroute a connection to a different connection. For example, the interposer 1604 may couple the IC package 1620 (e.g., a die) to a set of BGA conductive contacts of the coupling components 1616 for coupling to the circuit board 1602. In the example illustrated in FIG. 16, the IC package 1620 and the circuit board 1602 are attached to opposing sides of the interposer 1604; in other examples, the IC package 1620 and the circuit board 1602 may be attached to a same side of the interposer 1604. In some examples, three or more components may be interconnected by way of the interposer 1604.

In some examples, the interposer 1604 may be formed as a PCB, including multiple metal layers separated from one another by layers of dielectric material and interconnected by electrically conductive vias. In some examples, the interposer 1604 may be formed of an epoxy resin, a fiberglass-reinforced epoxy resin, an epoxy resin with inorganic fillers, a ceramic material, or a polymer material such as polyimide. In some examples, the interposer 1604 may be formed of alternate rigid or flexible materials that may include the same materials described above for use in a semiconductor substrate, such as silicon, germanium, and other group III-V and group IV materials. The interposer 1604 may include metal interconnects 1608 and vias 1610, including but not limited to through-silicon vias (TSVs) 1606. The interposer 1604 may further include embedded devices 1614, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1604. The package-on-interposer structure 1636 may take the form of any of the package-on-interposer structures known in the art.

The IC device assembly 1600 may include an IC package 1624 coupled to the first face 1640 of the circuit board 1602 by coupling components 1622. The coupling components 1622 may take the form of any of the examples discussed above with reference to the coupling components 1616, and the IC package 1624 may take the form of any of the examples discussed above with reference to the IC package 1620.

The IC device assembly 1600 illustrated in FIG. 16 includes a package-on-package structure 1634 coupled to the second face 1642 of the circuit board 1602 by coupling components 1628. The package-on-package structure 1634 may include a first IC package 1626 and a second IC package 1632 coupled together by coupling components 1630 such that the first IC package 1626 is disposed between the circuit board 1602 and the second IC package 1632. The coupling components 1628, 1630 may take the form of any of the examples of the coupling components 1616 discussed above, and the IC packages 1626, 1632 may take the form of any of the examples of the IC package 1620 discussed above. The package-on-package structure 1634 may be configured in accordance with any of the package-on-package structures known in the art.

FIG. 17 is a block diagram of an example electrical device 1700 that may include one or more of the example IC packages 100, 300. For example, any suitable ones of the components of the electrical device 1700 may include one or more of the device assemblies 1600, IC devices 1500, or dies 1402 disclosed herein, and may be arranged in the example IC packages 100, 300. A number of components are illustrated in FIG. 17 as included in the electrical device 1700, but any one or more of these components may be omitted or duplicated, as suitable for the application. In some examples, some or all of the components included in the electrical device 1700 may be attached to one or more motherboards. In some examples, some or all of these components are fabricated onto a single system-on-a-chip (SoC) die.

Additionally, in various examples, the electrical device 1700 may not include one or more of the components illustrated in FIG. 17, but the electrical device 1700 may include interface circuitry for coupling to the one or more components. For example, the electrical device 1700 may not include a display 1706, but may include display interface circuitry (e.g., a connector and driver circuitry) to which a display 1706 may be coupled. In another set of examples, the electrical device 1700 may not include an audio input device 1718 (e.g., microphone) or an audio output device 1708 (e.g., a speaker, a headset, earbuds, etc.), but may include audio input or output device interface circuitry (e.g., connectors and supporting circuitry) to which an audio input device 1718 or audio output device 1708 may be coupled.

The electrical device 1700 may include programmable circuitry 1702 (e.g., one or more processing devices). The programmable circuitry 1702 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1700 may include a memory 1704, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1704 may include memory that shares a die with the programmable circuitry 1702. This memory may be used as cache memory and may include embedded dynamic random access memory (eDRAM) or spin transfer torque magnetic random access memory (STT-MRAM).

In some examples, the electrical device 1700 may include a communication chip 1712 (e.g., one or more communication chips). For example, the communication chip 1712 may be configured for managing wireless communications for the transfer of data to and from the electrical device 1700. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1712 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1712 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1712 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1712 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1712 may operate in accordance with other wireless protocols in other examples. The electrical device 1700 may include an antenna 1722 to facilitate wireless communications and/or to receive other wireless communications (such as AM or FM radio transmissions).

In some examples, the communication chip 1712 may manage wired communications, such as electrical, optical, or any other suitable communication protocols (e.g., the Ethernet). As noted above, the communication chip 1712 may include multiple communication chips. For instance, a first communication chip 1712 may be dedicated to shorter-range wireless communications such as Wi-Fi or Bluetooth, and a second communication chip 1712 may be dedicated to longer-range wireless communications such as global positioning system (GPS), EDGE, GPRS, CDMA, WiMAX, LTE, EV-DO, or others. In some examples, a first communication chip 1712 may be dedicated to wireless communications, and a second communication chip 1712 may be dedicated to wired communications.

The electrical device 1700 may include battery/power circuitry 1714. The battery/power circuitry 1714 may include one or more energy storage devices (e.g., batteries or capacitors) and/or circuitry for coupling components of the electrical device 1700 to an energy source separate from the electrical device 1700 (e.g., AC line power).

The electrical device 1700 may include a display 1706 (or corresponding interface circuitry, as discussed above). The display 1706 may include any visual indicators, such as a heads-up display, a computer monitor, a projector, a touchscreen display, a liquid crystal display (LCD), a light-emitting diode display, or a flat panel display.

The electrical device 1700 may include an audio output device 1708 (or corresponding interface circuitry, as discussed above). The audio output device 1708 may include any device that generates an audible indicator, such as speakers, headsets, or earbuds.

The electrical device 1700 may include an audio input device 1718 (or corresponding interface circuitry, as discussed above). The audio input device 1718 may include any device that generates a signal representative of a sound, such as microphones, microphone arrays, or digital instruments (e.g., instruments having a musical instrument digital interface (MIDI) output).

The electrical device 1700 may include GPS circuitry 1716. The GPS circuitry 1716 may be in communication with a satellite-based system and may receive a location of the electrical device 1700, as known in the art.

The electrical device 1700 may include any other output device 1710 (or corresponding interface circuitry, as discussed above). Examples of the other output device 1710 may include an audio codec, a video codec, a printer, a wired or wireless transmitter for providing information to other devices, or an additional storage device.

The electrical device 1700 may include any other input device 1720 (or corresponding interface circuitry, as discussed above). Examples of the other input device 1720 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1700 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1700 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable more processor and/or memory capacity and/or capability to be incorporated into a given IC package without an increase in overall package size and/or to implement an IC package with a given processor and/or memory capacity in a smaller overall package size that is possible with known techniques. Examples disclosed herein include one or more semiconductor dies in one or more cavities within a stiffener in the package. Such semiconductor cavities can be communicatively coupled with other components (e.g., other semiconductor dies) in the package by way of a bridge die that extends across the stiffener to a base die in a central opening in the stiffener.

Further examples and combinations thereof include the following:

Example 1 includes an apparatus comprising a base die coupled to a package substrate, a stiffener adjacent the base die, the stiffener including a cavity, a semiconductor die different from the base die, the semiconductor die in the cavity in the stiffener, and a bridge to electrically couple the semiconductor die to the base die.

Example 2 includes any preceding clause(s) of example 1, wherein the semiconductor die is a first semiconductor die, the apparatus including a second semiconductor die different from the base die, different from the first semiconductor die, and different from the bridge.

Example 3 includes any preceding clause(s) of any one or more of examples 1-2, wherein the second semiconductor die is coupled to the base die adjacent the bridge, the second semiconductor die conductively coupled to the first semiconductor die through the base die and through the bridge.

Example 4 includes any preceding clause(s) of any one or more of examples 1-3, wherein the first semiconductor die includes at least one of a high-bandwidth memory device, a dynamic random access memory device, a graphics processing unit, a neural network processing unit, or a tensor processing unit, and the second semiconductor die includes at least one of a central processing unit or a graphics processing unit.

Example 5 includes any preceding clause(s) of any one or more of examples 1-4, wherein the second semiconductor die is in the cavity in the stiffener.

Example 6 includes any preceding clause(s) of any one or more of examples 1-5, wherein the cavity is a first cavity, the stiffener has a second cavity, and the second semiconductor die is in the second cavity, the second cavity distinct and separate from the first cavity.

Example 7 includes any preceding clause(s) of any one or more of examples 1-6, including a thermally conductive material to fill a gap between the semiconductor die and a wall of the cavity.

Example 8 includes any preceding clause(s) of any one or more of examples 1-7, wherein the thermally conductive material includes a liquid coolant.

Example 9 includes any preceding clause(s) of any one or more of examples 1-8, wherein the thermally conductive material includes at least one of a thermally conductive polymer or a thermal paste.

Example 10 includes any preceding clause(s) of any one or more of examples 1-9, including a sealant to enclose the thermally conductive material within the cavity.

Example 11 includes any preceding clause(s) of any one or more of examples 1-10, wherein the package substrate includes a first surface that faces towards the stiffener, the stiffener includes a second surface that faces away from the first surface, and the cavity extends into the stiffener from the second surface to a recessed surface in the stiffener, the recessed surface faces away from the first surface.

Example 12 includes any preceding clause(s) of any one or more of examples 1-11, wherein the semiconductor die includes a third surface that faces away from the first surface, the third surface substantially flush with the second surface.

Example 13 includes any preceding clause(s) of any one or more of examples 1-12, wherein the semiconductor die is a first semiconductor die, and the bridge is a second semiconductor die that includes active transistors.

Example 14 includes any preceding clause(s) of any one or more of examples 1-13, wherein the bridge is a passive component that includes at least one of a glass substrate, an organic substrate, or a ceramic substrate.

Example 15 includes an apparatus comprising a first die conductively coupled to a package substrate, a second die adjacent to the first die, the second die conductively coupled to the first die through a bridge, the first die between the bridge and the package substrate, the second die between the bridge and the package substrate, and a stiffener on the package substrate, a portion of the stiffener between the first die and the second die.

Example 16 includes any preceding clause(s) of example 15, wherein the portion is a first portion, and a second portion of the stiffener is between the second die and the package substrate.

Example 17 includes any preceding clause(s) of any one or more of examples 15-16, wherein the second die is one die in a stack of multiple dies, the portion of the stiffener between the first die and the stack of multiple dies.

Example 18 includes any preceding clause(s) of any one or more of examples 15-17, wherein the portion is a first portion of the stiffener, the first portion defines a wall of a first cavity in the stiffener, the second die is in the first cavity, and the apparatus includes a third die, the third die in at least one of the first cavity or a second cavity in the stiffener, the second cavity defined by a second portion of the stiffener between the first die and the third die.

Example 19 includes an apparatus comprising a first die including a first surface facing towards a package substrate and a second surface facing away from the package substrate, a stiffener including a third surface facing towards the package substrate and a fourth surface facing away from the package substrate, the stiffener including a recess in the fourth surface, and a second die in the recess, the second die including a fifth surface facing towards the package substrate and a sixth surface facing away from the package substrate.

Example 20 includes any preceding clause(s) of example 19, including a bridge conductively coupled to the second surface of the first die and to the sixth surface of the second die.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a base die coupled to a package substrate;
a stiffener adjacent the base die, the stiffener including a cavity;
a semiconductor die different from the base die, the semiconductor die in the cavity in the stiffener; and
a bridge to electrically couple the semiconductor die to the base die.

2. The apparatus of claim 1, wherein the semiconductor die is a first semiconductor die, the apparatus including a second semiconductor die different from the base die, different from the first semiconductor die, and different from the bridge.

3. The apparatus of claim 2, wherein the second semiconductor die is coupled to the base die adjacent the bridge, the second semiconductor die conductively coupled to the first semiconductor die through the base die and through the bridge.

4. The apparatus of claim 2, wherein the first semiconductor die includes at least one of a high-bandwidth memory device, a dynamic random access memory device, a graphics processing unit, a neural network processing unit, or a tensor processing unit, and the second semiconductor die includes at least one of a central processing unit or a graphics processing unit.

5. The apparatus of claim 2, wherein the second semiconductor die is in the cavity in the stiffener.

6. The apparatus of claim 2, wherein the cavity is a first cavity, the stiffener has a second cavity, and the second semiconductor die is in the second cavity, the second cavity distinct and separate from the first cavity.

7. The apparatus of claim 1, including a thermally conductive material to fill a gap between the semiconductor die and a wall of the cavity.

8. The apparatus of claim 7, wherein the thermally conductive material includes a liquid coolant.

9. The apparatus of claim 7, wherein the thermally conductive material includes at least one of a thermally conductive polymer or a thermal paste.

10. The apparatus of claim 7, including a sealant to enclose the thermally conductive material within the cavity.

11. The apparatus of claim 1, wherein the package substrate includes a first surface that faces towards the stiffener, the stiffener includes a second surface that faces away from the first surface, and the cavity extends into the stiffener from the second surface to a recessed surface in the stiffener, the recessed surface faces away from the first surface.

12. The apparatus of claim 11, wherein the semiconductor die includes a third surface that faces away from the first surface, the third surface substantially flush with the second surface.

13. The apparatus of claim 1, wherein the semiconductor die is a first semiconductor die, and the bridge is a second semiconductor die that includes active transistors.

14. The apparatus of claim 1, wherein the bridge is a passive component that includes at least one of a glass substrate, an organic substrate, or a ceramic substrate.

15. An apparatus comprising:
a first die conductively coupled to a package substrate;
a second die adjacent to the first die, the second die conductively coupled to the first die through a bridge, the first die between the bridge and the package substrate, the second die between the bridge and the package substrate; and
a stiffener on the package substrate, a portion of the stiffener between the first die and the second die.

16. The apparatus of claim 15, wherein the portion is a first portion, and a second portion of the stiffener is between the second die and the package substrate.

17. The apparatus of claim 15, wherein the second die is one die in a stack of multiple dies, the portion of the stiffener between the first die and the stack of multiple dies.

18. The apparatus of claim 15, wherein the portion is a first portion of the stiffener, the first portion defines a wall of a first cavity in the stiffener, the second die is in the first cavity, and the apparatus includes a third die, the third die in at least one of the first cavity or a second cavity in the stiffener, the second cavity defined by a second portion of the stiffener between the first die and the third die.

19. An apparatus comprising:
a first die including a first surface facing towards a package substrate and a second surface facing away from the package substrate;
a stiffener including a third surface facing towards the package substrate and a fourth surface facing away from the package substrate, the stiffener including a recess in the fourth surface; and
a second die in the recess, the second die including a fifth surface facing towards the package substrate and a sixth surface facing away from the package substrate.

20. The apparatus of claim 19, including a bridge conductively coupled to the second surface of the first die and to the sixth surface of the second die.
